(19) United States
(12) Patent Application Publication
(10) Pub. No.: US 2012/0291842 A1
(43) Pub. Date: Nov. 22, 2012

(54) BACK SHEET FOR SOLAR CELL, METHOD FOR PRODUCING THE SAME, AND SOLAR CELL MODULE

(76) Inventors: Akira Hatakeyama, Kanagawa (JP); Shinji Tanaka, Kanagawa (JP)

(21) Appl. No.: 13/522,471

(22) PCT Filed: Jan. 18, 2011
(86) PCT No.: PCT/JP2011/051531

§ 371 Date: Jul. 16, 2012

(30) Foreign Application Priority Data
Jan. 18, 2010 (JP) 2010-008596

(51) Int. Cl. H01L 31/0216; H01L 31/18; H01L 31/042

(52) U.S. Cl. 136/244; 136/256; 427/58

(57) ABSTRACT

A back sheet for a solar cell, including on a polymer substrate: a colored layer which contains a first binder and 2.5 g/m2 to 8.5 g/m2 of a pigment; and an easy adhesion layer which contains 0.05 g/m2 to 5 g/m2 of a second binder and 5% by mass to 400% by mass of inorganic fine particles based on the content of the second binder and has an adhesive power of 10 N/cm or greater with respect to an ethylene-vinyl acetate sealing material, in this order from the side of the polymer substrate.

### TECHNICAL FIELD

The present invention relates to a back sheet for a solar cell which is installed on a side opposite to a sunlight incident side of a solar cell device, a method for producing the back sheet, and a solar cell module.

### BACKGROUND ART

Solar cells are power generating systems which do not discharge carbon dioxide during power generation and have little adverse effect on the environment, and in recent years, solar cells have been rapidly popularized.

A solar cell module in general has a structure in which a solar cell is sandwiched between a front surface glass on a side where sunlight enters, and a so-called back sheet that is disposed on a side opposite to a side where sunlight enters (rear surface side). The spaces between the front surface glass and the solar cell and between the solar cell and the back sheet are respectively sealed with an EVA (ethylene-vinyl acetate) resin or the like.

The back sheet has a function of preventing the penetration of moisture from the rear surface of a solar cell module, and glass, a fluororesin and the like have been traditionally used. However, in recent years, polyester has been increasingly used from the viewpoint of cost. Furthermore, the back sheet is not a mere polymer sheet, but may be imparted with various functions such as those described below.

Regarding the functions described above, for example, there may be a demand for imparting a reflection performance by adding white inorganic fine particles such as titanium oxide to the back sheet. This is because when the portion of light in the sunlight that is incident through the front surface of the module and passes through the cell is diffusely reflected and returned to the cell, the power generation efficiency is increased. In this regard, an example of a white polyethylene terephthalate film with added white inorganic fine particles has been disclosed (see, for example, Japanese Patent Application Laid-Open (JP-A) No. 2003-060218 and JP-A No. 2006-210557), and an example of a rear surface protective sheet having a white ink layer containing a white pigment has also been disclosed (see, for example, JP-A No. 2006-210557).

Furthermore, there are cases where the back sheet is required to have decorativeness. In this regard, there has been disclosed an example of a back sheet for a solar cell to which a perylene pigment, which is a black pigment, has been added to improve decorativeness (see, for example, JP-A No. 2007-128943).

Furthermore, there are cases where an easy adhesion layer is provided as the outermost layer of a back sheet in order to obtain strong adhesion between the back sheet and an EVA sealing material. In this regard, there has been disclosed a technology of providing a thermally adhesive layer on a white polyethylene terephthalate film (see, for example, JP-A No. 2003-060218).

In order to impart functions such as described above, the back sheet has a structure in which a layer having another function is laminated on a support. Examples of lamination methods may include a method of affixing sheets having various functions on a support. For example, there has been disclosed a method of forming a back sheet by affixing plural resin films (see, for example, JP-A No. 2002-100788). Furthermore, as a method of forming a back sheet at lower cost than the method of affixing, there has been disclosed a method of coating layers having various functions on a support (see, for example, JP-A No. 2006-210557 and JP-A No. 2007-128943).

However, although there are available technologies disclosed in connection with the method of forming a back sheet by affixing, these technologies involve high cost, are inferior in interlayer adhesiveness in long-term use, and are unsatisfactory in terms of durability. That is, since back sheets are directly exposed to moisture, heat or light, the back sheets are required to have durability with respect thereto. Particularly, back sheets generally have a structure adhered to an EVA sealing material, and in this case, the adhesion durability over time between the back sheet and the EVA is extremely important. Furthermore, the adhesion durability between the support and the respective layers is also indispensable.

There have been also disclosed methods involving coating, but these methods are not yet satisfactory in providing a back sheet for a solar cell achieving a good balance between light reflectivity or decorativeness and adhesiveness to an EVA sealing material.

As described above, in the current situation, there has not yet been provided a back sheet for a solar cell, which has both adhesiveness to EVA sealing materials that lasts for a long time and other functions (for example, reflection performance or decoration), and which, at the same time, can be produced at low cost and can provide satisfactory durability with respect to moisture and heat.

### SUMMARY OF INVENTION

It is an object of the invention to provide a back sheet for a solar cell, which has both adhesion durability with EVA sealing materials that lasts for a long time and reflectivity or decorativeness, and which can be produced at low cost. Furthermore, it is an object of the invention to provide a back sheet for a solar cell having satisfactory durability against moisture and heat.

Furthermore, it is an object of the invention to provide a method for producing a back sheet for a solar cell, which can produce at low cost a back sheet for a solar cell that has both adhesion durability with EVA sealing materials that lasts for a long time and reflectivity or decorativeness. Furthermore, it is an object of the invention to provide a method for producing a back sheet for a solar cell, which can produce at low cost a back sheet for a solar cell having satisfactory durability against moisture and heat.

Furthermore, it is an object of the invention to provide an inexpensive solar cell module having stable power generation efficiency.

Exemplary embodiments for achieving the above objects are as follows.

<1> A back sheet for a solar cell, comprising on a polymer substrate:

a colored layer which contains a first binder and 2.5 g/m² to 8.5 g/m² of a pigment; and

an easy adhesion layer which contains 0.05 g/m² to 5 g/m² of a second binder and 5% by mass to 400% by mass of inorganic fine particles based on the content of the second binder and has an adhesive power of 10 N/cm or greater with respect to an ethylene-vinyl acetate sealing material,

in this order from the side of the polymer substrate.

<2> The back sheet for a solar cell according to <1>, wherein the colored layer further contains 5% by mass to 50% by mass of a crosslinking agent based on the content of the first binder.

<3> The back sheet for a solar cell according to <1> or <2>, wherein the easy adhesion layer further contains 5% by mass to 50% by mass of a crosslinking agent based on the content of the second binder.

<4> The back sheet for a solar cell according to any one of <1> to <3>, wherein the adhesive power with respect to the sealing material after storage of the back sheet for 48 hours in an atmosphere at 120° C. and 100% RH is at least 75% of the adhesive power with respect to the sealing material prior to the storage.

<5> The back sheet for a solar cell according to any one of <1> to <4>, wherein the colored layer is disposed directly, or via an undercoat layer having a thickness of 2 μm or less, on a surface of the polymer substrate.

<6> The back sheet for a solar cell according to any one of <1> to <5>, wherein the pigment is a white pigment, and a reflectance of light having a wavelength of 550 nm on a surface of the back sheet where the colored layer and the easy adhesion layer are provided is 75% or greater.

<7> The back sheet for a solar cell according to any one of <1> to <6>, wherein the polymer substrate comprises a polyester having a carboxy group content of 35 equivalents/ton or less.

<8> The back sheet for a solar cell according to any one of <1> to <7>, wherein the colored layer and the easy adhesion layer are formed by coating.

<9> A solar cell module comprising a transparent substrate through which sunlight enters, a solar cell device, and the back sheet for a solar cell according to any one of <1> to <8>.

<10> A method for producing a back sheet for a solar cell, the method comprising applying, on a polymer substrate, a first coating liquid which contains a first binder and a pigment, and a second coating liquid which contains a second binder and inorganic fine particles, in this order from the polymer substrate side, thereby forming a colored layer which contains the first binder and 2.5 g/m² to 8.5 g/m² of the pigment, and an easy adhesion layer which contains 0.05 g/m² to 5 g/m² of the second binder and 5% by mass to 400% by mass of the inorganic fine particles based on the content of the second binder and has an adhesive power of 10 N/cm or greater with respect to an ethylene-vinyl acetate sealing material.

<11> The method for producing a back sheet for a solar cell according to <10>, wherein the first coating liquid further contains a solvent and is an aqueous coating liquid in which 60% by mass or more of the solvent is water.

<12> The method for producing a back sheet for a solar cell according to <10> or <11>, wherein the colored layer is formed on the polymer substrate by applying the first coating liquid directly, or via an undercoat layer having a thickness of 2 μm or less, on a surface of the polymer substrate.

According to an aspect of the invention, there can be provided a back sheet for a solar cell, which has both adhesion durability with EVA sealing materials that lasts for a long time and reflectivity or decorativeness, and which can be produced at low cost. Furthermore, there can be provided a back sheet for a solar cell having satisfactory durability against moisture and heat.

Furthermore, according to an aspect of the invention, there can be provided a method for producing a back sheet for a solar cell, which can produce at low cost a back sheet for a solar cell that has both adhesion durability with EVA sealing materials that lasts for a long time and reflectivity or decorativeness. Furthermore, there can be provided a method for producing a back sheet for a solar cell, which can produce at low cost a back sheet for a solar cell having satisfactory durability against moisture and heat.

Furthermore, according to an aspect of the invention, there can be provided an inexpensive solar cell module having stable power generation efficiency.

### DESCRIPTION OF EMBODIMENTS

Hereinafter, a back sheet for a solar cell, a method for production thereof, and a solar cell module of the invention will be described in detail.

(Back Sheet for a Solar Cell and Method for Producing the Same)

The back sheet for a solar cell of the invention comprises, on a polymer substrate, sequentially from the polymer substrate side, a colored layer which contains a binder and 2.5 g/m² to 8.5 g/m² of a pigment, and an easy adhesion layer which contains 0.05 g/m² to 5 g/m² of a binder and 5% by mass to 400% by mass of inorganic fine particles based on the content of the binder, and has an adhesive power of 10 N/cm or greater with respect to an ethylene-vinyl acetate sealing material.

In the invention, since a colored layer (preferably, a reflective layer) which contains a predetermined amount of a pigment (preferably, a white pigment) is laminated, and an easy adhesion layer, which contains a predetermined amount of a binder and inorganic fine particles and is imparted with adhesiveness to an EVA sealing agent, is laminated on the colored layer, the back sheet has light reflectivity or decorativeness suitable for the use in solar cells, also has excellent adhesion to the cell body (particularly, adhesion to an EVA sealing agent that seals a solar cell device), and can be maintained stably without causing peeling or the like over time in a humid and hot environment. Thus, the back sheet can stably maintain a power generating performance for a long time.

—Polymer Substrate—

Examples of the polymer substrate include a polyester; a polyolefin such as polypropylene or polyethylene; or a fluoropolymer such as polyvinyl fluoride. Among these, from the viewpoint of cost or mechanical strength, a polyester is preferred.

The polyester used as the substrate (support) according to the invention may be a linear saturated polyester which is synthesized from an aromatic dibasic acid or an ester-forming derivative thereof and a diol or an ester-forming derivative thereof. Specific examples of such a polyester include polyethylene terephthalate, polyethylene isophthalate, polybutylene terephthalate, poly(1,4-cyclohexylenedimethylene terephthalate), and polyethylene-2,6-naphthalate. Among these, polyethylene terephthalate or polyethylene-2,6-naphthalate is particularly preferable from the viewpoint of the balance of mechanical properties, cost and the like.

The polyester may be a homopolymer or may be a copolymer. Furthermore, the polyester may be blended with a small amount of another type of resin, for example, a polyimide.

In order to prepare the polyester according to the invention by polymerization, from the viewpoint of suppressing the content of carboxy group to a predetermined range or less, it is preferable to use an Sb compound, a Ge compound or a Ti compound as a catalyst, and among them, a Ti compound is particularly preferable. In the case of using a Ti compound, an embodiment of performing polymerization by using the Ti compound as a catalyst in an amount of from 1 ppm to 30 ppm, and more preferably from 3 ppm to 15 ppm, is preferable. When the amount of the Ti compound is in the range described above, the content of terminal carboxy groups can be adjusted to the range shown below, and the hydrolyzability of the polymer substrate can be maintained at a low level.

In the synthesis of a polyester using a Ti compound, for example, the methods described in Japanese Examined Patent Application Publication (JP-B) No. 8-301198, Japanese Patents Nos. 2543624, 3335683, 3717380, 3897756, 3962226, 3979866, 3996871, 4000867, 4053837, 4127119, 4134710, 4159154, 4269704 and 4313538 can be applied.

The carboxy group content in the polyester is preferably 50 equivalents/t or less, and more preferably 35 equivalents/t or less. When the carboxy group content is 50 equivalents/t or less, the resistance to hydrolysis can be maintained, and a decrease in the strength after the passage of time under heat and moisture can be suppressed. The lower limit of the carboxy group content is preferably 2 equivalents/t, in view of maintaining the adhesiveness to the layer formed adjacent to the polyester (for example, colored layer).

The carboxy group content in the polyester can be adjusted by the kind of the polymerization catalyst and the conditions for film formation (temperature or time for film formation).

The polyester according to the invention is preferably solid state polymerized after polymerization. Thereby, the preferable carboxy group content can be achieved. The solid state polymerization may be carried out by a continuous method (a method of packing a resin in a tower, allowing this resin to flow slowly in the tower for a predetermined time while heating the resin, and then discharging the resin), or may be carried out by a batch method (a method of feeding a resin into a vessel and heating the resin for a predetermined time). Specifically, the methods described in Japanese Patents Nos. 2621563, 3121876, 3136774, 3603585, 3616522, 3617340, 3680523, 3717392, 4167159 and the like can be applied to the solid state polymerization.

The temperature of the solid state polymerization is preferably from 170° C. to 240° C., more preferably from 180° C. to 230° C., and even more preferably from 190° C. to 220° C. Furthermore, the time for the solid state polymerization is preferably from 5 hours to 100 hours, more preferably from 10 hours to 75 hours, and even more preferably from 15 hours to 50 hours. The solid state polymerization is preferably carried out in a vacuum or in a nitrogen atmosphere.

The polyester substrate according to the invention is preferably, for example, a biaxially stretched film produced by melt extruding the polyester mentioned above into a film form, cooling and solidifying the polyester with a casting drum to obtain an unstretched film, stretching this unstretched film at Tg to (Tg+60)° C. in the longitudinal direction such that the total stretching ratio after one round or two or more rounds is 3 times to 6 times, and then stretching the film at Tg to (Tg+60)° C. in the width direction such that the stretching ratio is 3 to 5 times.

Furthermore, the polyester substrate may be optionally subjected to a heat treatment at 180° C. to 230° C. for 1 second to 60 seconds.

The thickness of the polymer substrate (particularly, polyester substrate) is preferably about 25 μm to 300 μm. When the thickness is 25 μm or greater, the polymer substrate is satisfactory in terms of the mechanical strength, and when the thickness is 300 μm or less, it is advantageous in view of cost.

Particularly, the polyester substrate tends to be poor in the resistance to hydrolysis and to not endure long-term use as the thickness is increased. In the invention, when the thickness is from 120 μm to 300 μm and the carboxy group content in the polyester is 2 equivalents/t to 50 equivalents/t, an effect of enhancing the durability to moisture and heat is further achieved.

—Colored Layer—

The colored layer according to the invention contains at least a pigment in an amount of 2.5 g/m² to 8.5 g/m², and a binder. This colored layer may optionally further include other components such as various additives.

A first function of the colored layer according to the invention is to increase the power generation efficiency of a solar cell module by reflecting the portion of light that has passed through the solar cell and has arrived at the back sheet without being used in power generation in the incident light and returning the portion of light to the solar cell. A second function is to enhance the decorativeness of the external appearance when the solar cell module is viewed from the side through which sunlight enters (front surface side). In general, when a solar cell module is viewed from the front surface side, the back sheet is seen around the solar cell. Thus, by providing the back sheet with a colored layer, the decorativeness is enhanced, and the appearance can be improved.

(Pigment)

The colored layer according to the invention contains at least one pigment.

As the pigment, for example, an inorganic pigment such as titanium oxide, barium sulfate, silicon oxide, aluminum oxide, magnesium oxide, calcium carbonate, kaolin, talc, ultramarine blue, Prussian blue, or carbon black; or an organic pigment such as phthalocyanine blue or phthalocyanine green can be appropriately selected and incorporated.

The colored layer according to the invention contains a pigment in an amount in the range of 2.5 g/m² to 8.5 g/m². If the content of the pigment in the colored layer is less than 2.5 g/m², the required coloration is not achieved, and the required reflectance or decorativeness is not obtained. Furthermore, if the content of the pigment in the colored layer is greater than 8.5 g/m², the surface state of the colored layer is deteriorated, and the film strength is decreased.

Among them, a more preferable content of the pigment is in the range of 4.5 g/m² to 8.0 g/m².

The volume average particle diameter of the pigment is preferably 0.03 μm to 0.8 μm, and more preferably about 0.15 μm to 0.5 μm. When the average particle diameter is in the range mentioned above, the efficiency of light reflection is high. The average particle diameter is a value measured with a laser analysis/scattering type particle diameter distribution measuring apparatus LA950 (trade name, manufactured by Horiba, Ltd.).

(Binder)

The colored layer of the invention contains at least one binder.

The content of the binder is preferably in the range of 15% by mass to 200% by mass, and more preferably in the range of 17% by mass to 100% by mass, based on the content of the pigment. When the content of the binder is 15% by mass or more, the strength of the colored layer is sufficiently obtained, and when the content is 200% by mass or less, the reflectance or decorativeness can be maintained satisfactorily.

Examples of the binder suitable for the colored layer according to the invention include a polyester, a polyurethane, an acrylic resin and a polyolefin, and from the viewpoint of durability, an acrylic resin or a polyolefin is preferable. Furthermore, as the acrylic resin, a composite resin of acrylic resin and silicone is also preferable. Preferable examples of the binder include, as examples of the polyolefin, CHEMIPEARL S-120 and S-75N (trade names, all manufactured by Mitsui Chemicals, Inc.); as examples of the acrylic resin, JURYMER ET-410 and SEK-301 (trade names, all manufactured by Nihon Junyaku Co., Ltd.); and as examples of the composite resin of acrylic resin and silicone, CERANATE WSA1060 and WSA1070 (trade names, all manufactured by DIC Corp.), H7620, H7630 and H7650 (trade names, all manufactured by Asahi Kasei Chemicals Corp.).

(Additives)

The colored layer according to the invention may optionally further contain additives such as a crosslinking agent, a surfactant and a filler, in addition to the binder and the pigment.

Examples of the crosslinking agent include epoxy, isocyanate, melamine, carbodiimide and oxazoline crosslinking agents. Among them, oxazoline crosslinking agents are preferable, and specifically, those that can be used in the easy adhesion layer that will be described below can be preferably used.

In the case of adding a crosslinking agent, the amount added is preferably 5% by mass to 50% by mass, and more preferably 10% by mass to 40% by mass, based on the content of the binder in the colored layer. When the amount of the crosslinking agent added is 5% by mass or greater, a sufficient crosslinking effect is obtained while the strength and adhesiveness of the colored layer is retained. When the amount added is 50% by mass or less, a prolonged pot life of the coating liquid can be maintained.

Examples of the surfactant include known anionic or nonionic surfactants. When a surfactant is added, the amount added is preferably 0.1 mg/m² to 15 mg/m², and more preferably 0.5 mg/m² to 5 mg/m². When the amount of the surfactant added is 0.1 mg/m² or greater, the occurrence of cissing is suppressed, and satisfactory layer formation may be achieved. When the amount added is 15 mg/m² or less, the adhesion can be satisfactorily achieved.

The colored layer according to the invention may further contain a filler such as silica, in addition to the pigment described above. In the case of adding a filler, the amount added is preferably 20% by mass or less, and more preferably 15% by mass or less, based on the content of the binder in the colored layer. When the amount of the filler added is 20% by mass or less, a required reflectance or decorativeness can be obtained while a decrease in the content of the pigment is suppressed.

(Method for Forming Colored Layer)

The formation of the colored layer can be carried out by a method of affixing a polymer sheet containing a pigment to a substrate; a method of co-extruding the colored layer during the formation of the substrate; a method based on coating; or the like. Specifically, the colored layer can be formed directly, or via an undercoat layer having a thickness of 2 μm or less, on the surface of a polymer substrate by performing affixing, co-extruding, coating or the like. The colored layer thus formed may be in a state of being in direct contact with the surface of the polymer substrate, or may be in a state of being laminated via an undercoat layer on the surface of the polymer substrate.

Among the methods described above, a method based on coating is preferable from the viewpoint that the method is convenient, and it is possible to form a uniform thin film.

In the case of performing coating, known coating methods using, for example, a gravure coater or a bar coater, can be used.

The coating liquid may be an aqueous type using water as a coating solvent, or a solvent type using an organic solvent such as toluene or methyl ethyl ketone. Among them, from the viewpoint of environmental load, it is preferable to use water as the solvent. The coating solvent may be such that one kind may be used alone, or two or more kinds may be used in mixture.

(Undercoat Layer)

In the back sheet for a solar cell of the invention, an undercoat layer may be provided between the polymer substrate (support) and the colored layer. The thickness of the undercoat layer is preferably in the thickness range of 2 μm or less, more preferably 0.05 μm to 2 μm, and even more preferably 0.1 μm to 1.5 μm. When the thickness is 2 μm or less, the surface state can be maintained satisfactorily. Furthermore, when the thickness is 0.05 μm or greater, it is easy to secure necessary adhesiveness.

The undercoat layer can contain a binder. Examples of the binder that can be used include a polyester, a polyurethane, an acrylic resin, and a polyolefin. Furthermore, the undercoat layer may contain, in addition to the binder, an epoxy crosslinking agent, an isocyanate crosslinking agent, a melamine crosslinking agent, a carbodiimide crosslinking agent or an oxazoline crosslinking agent; an anionic or nonionic surfactant; a filler such as silica, and the like.

There are no particular limitations on the method of coating the undercoat layer or the solvent for the coating liquid used.

As the method of coating, for example, a gravure coater or a bar coater can be used.

The solvent used in the coating liquid may be water, or may be an organic solvent such as toluene or methyl ethyl ketone. Regarding the solvent, one kind may be used alone, or two or more kinds may be used in a mixture.

The coating may be carried out on a polymer substrate after biaxial stretching, or may be carried out by a method of coating on a polymer substrate after uniaxial stretching, and then stretching the polymer substrate in a direction different from the first stretching. Furthermore, it is also acceptable to perform coating on a substrate prior to stretching, and then to stretch the substrate in two directions.

(Properties)

When a reflective layer is formed by adding a white pigment to the colored layer, the reflectance of light of 550 nm on the surface of the side where the colored layer and the easy adhesion layer are provided, is preferably 75% or greater. Here, the light reflectance is a ratio of the amount of light that enters through the surface of the easy adhesion layer, is reflected on the reflective layer, and exits through the easy adhesion layer, with respect to the amount of incident light.

When the light reflectance is 75% or greater, the light that has passed through the cell and entered the interior, can be effectively returned to the cell, and thus the effect of enhancing the power generation efficiency is significant. The light reflectance can be adjusted to 75% or greater by controlling the content of the coloring agent in the range of 2.5 g/m² to 8.5 g/m².

In the case of constructing the colored layer as a reflective layer, the thickness of the reflective layer is preferably 1 μm to 20 μm, and more preferably about 1.5 μm to 10 μm. When this thickness is 1 μm or greater, the necessary decorativeness or reflectance can be obtained. Furthermore, when the thickness is 20 μm or less, the surface state can be maintained satisfactorily.

—Easy Adhesion Layer—

The easy adhesion layer according to the invention includes a binder in an amount of 0.05 g/m² to 5 g/m² and inorganic fine particles in an amount of 5% by mass to 400% by mass based on the content of the binder, and has an adhesive power of 10 N/cm or greater with respect to an ethylene-vinyl acetate sealing material. The easy adhesion layer may optionally further include other components such as additives.

The easy adhesion layer is a layer for firmly adhering the back sheet to a sealing material that seals the solar cell device (hereinafter, also referred to as power generation device) in the cell body. Specifically, the easy adhesion layer according to the invention is provided such that the adhesive power with respect to the ethylene-vinyl acetate (EVA; ethylene-vinyl acetate copolymer) sealing material which seals the power generation device in the cell body, is 10 N/cm or greater, and preferably 20 N/cm or greater. If this adhesive power is less than 10 N/cm, the moisture and heat resistance for maintaining adhesiveness is not satisfactory, and peeling occurs as time lapses, so that a solar cell module having excellent long-time durability cannot be obtained. The adhesive power is obtained by a method of regulating the amounts of the binder and inorganic fine particles in the easy adhesion layer to the ranges described above. Another method may be a method of applying a corona treatment to the surface of the back sheet which is adhered to the sealing material.

(Binder)

The easy adhesion layer contains at least one binder.

Examples of the binder that is suitable for the easy adhesion layer include a polyester, a polyurethane, an acrylic resin, and a polyolefin. Among them, an acrylic resin and a polyolefin are preferable from the viewpoint of durability. Furthermore, a composite resin of acrylic resin and silicone is also preferable as the acrylic resin.

Preferable examples of the binder include, as specific examples of the polyolefin, CHEMIPEARL S-120 and S-75N (trade names, all manufactured by Mitsui Chemicals, Inc.); as specific examples of the acrylic resin, JURYMER ET-410 and SEK-301 (trade names, all manufactured by Nihon Junyaku Co., Ltd.); and as specific examples of the composite resin of acrylic resin and silicone, CERANATE WSA1060 and WSA1070 (trade names, all manufactured by DIC Corp.), H7620, H7630 and H7650 (trade names, all manufactured by Asahi Kasei Chemicals Corp.).

The content of the binder in the easy adhesion layer is in the range of 0.05 g/m² to 5 g/m². Inter alia, the content is preferably in the range of 0.08 g/m² to 3 g/m². If the content of the binder is less than 0.05 g/m², a desired adhesive power cannot be obtained, and if the content is greater than 5 g/m², a satisfactory surface state cannot be obtained.

(Fine Particles)

The easy adhesion layer contains at least one kind of inorganic fine particles.

Examples of the inorganic fine particles include fine particles of silica, calcium carbonate, magnesium oxide, magnesium carbonate and tin oxide. Among them, the fine particles of tin oxide and silica are preferable from the viewpoint that the decrease in adhesiveness is small when the easy adhesion layer is exposed to a hot and humid atmosphere.

The volume average particle diameter of the inorganic fine particles is preferably about 10 nm to 700 nm, and more preferably about 20 nm to 300 nm. When the particle diameter is in this range, more satisfactory adhesiveness can be obtained. The particle diameter is a value measured with a laser analysis/scattering type particle diameter distribution measuring apparatus LA950 (trade name, manufactured by Horiba, Ltd.).

There are no particular limitations on the shape of the inorganic fine particles, and any of a spherical shape, an amorphous shape, a needle shape and the like can be used.

The content of the inorganic fine particles is in the range of 5% by mass to 400% by mass, based on the content of the binder in the easy adhesion layer. If the content of the inorganic fine particles is less than 5% by mass, satisfactory adhesiveness cannot be retained when the easy adhesion layer is exposed to a hot and humid atmosphere, and if the content is greater than 400% by mass, the surface state of the easy adhesion layer is deteriorated.

Inter alia, the content of the inorganic fine particles is preferably in the range of 50% by mass to 300% by mass.

(Crosslinking Agent)

The easy adhesion layer can contain at least one crosslinking agent.

Examples of a crosslinking agent that is suitable for the easy adhesion layer include epoxy, isocyanate, melamine, carbodiimide and oxazoline crosslinking agents. Among them, from the viewpoint of securing adhesiveness after a lapse of time under heat and moisture, an oxazoline crosslinking agent is particularly preferable.

Specific examples of the oxazoline crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis-(2-oxazoline), 2,2′-m-phenylene-bis-(4,4′-dimethyl-2-oxazoline), bis-(2-oxazolinylcyclohexane)sulfide, and bis-(2-oxazolinylnorbornane)sulfide. Furthermore, (co)polymers of these compounds are also preferably used.

As the compound having an oxazoline group, EPOCROS K2010E, EPOCROS K2020E, EPOCROS K2030E, EPOCROS WS-500, EPOCROS WS-700 (trade names, all manufactured by Nippon Shokubai co., Ltd.) and the like can also be used.

The content of the crosslinking agent in the easy adhesion layer is preferably 5% by mass to 50% by mass based on the content of the binder in the easy adhesion layer, and inter alia, more preferably 20% by mass to 40% by mass. When the content of the crosslinking agent is 5% by mass or greater, a satisfactory crosslinking effect is obtained, and the strength or adhesiveness of the colored layer can be maintained. When the content is 50% by mass or less, a prolonged pot life of the coating liquid can be maintained.

(Additives)

The easy adhesion layer according to the invention may optionally contain a known matting agent such as polystyrene, polymethyl methacrylate or silica; a known anionic or nonionic surfactant; and the like.

(Method of Forming Easy Adhesion Layer)

The formation of the easy adhesion layer may be carried out by a method of affixing a polymer sheet having easy adhesiveness to a substrate, or a method based on coating. Among them, the method based on coating is preferable from the viewpoint that the method is convenient, and it is possible to form a uniform thin film.

In regard to the coating method, known coating methods using, for example, a gravure coater or a bar coater can be used.

The coating solvent used in the preparation of the coating liquid may be water, or may be an organic solvent such as toluene or methyl ethyl ketone. The coating solvent may be such that one kind may be used alone, or two or more kinds may be used in a mixture.

(Properties)

There are no particular limitations on the thickness of the easy adhesion layer, but the thickness is usually preferably 0.05 μm to 8 μm, and more preferably in the range of 0.1 μm to 5 μm. When the thickness of the easy adhesion layer is 0.05 μm or greater, the necessary adhesiveness can be suitably obtained, and when the thickness is 8 μm or less, the surface state becomes more satisfactory.

Furthermore, the easy adhesion layer of the invention needs to be transparent in order not to reduce the effect of the colored layer.

In addition, the back sheet for a solar cell of the invention is preferably such that the adhesive power with respect to an EVA sealing material after storage of the back sheet for 48 hours in an atmosphere at 120° C. and 100% RH is at least 75% of the adhesive power with respect to the EVA sealing material prior to the storage. The back sheet for a solar cell of the invention has an easy adhesion layer which contains a predetermined amount of a binder and a predetermined amount, based on the content of the binder, of inorganic fine particles, and has an adhesive power of 10 N/cm or greater with respect to an EVA sealing material as described above, so that even after the storage such as described above, an adhesive power of at least 75% of the adhesive power prior to storage is obtained. Therefore, in a solar cell module thus produced, peeling of the back sheet and a decrease in the power generation performance caused thereby are suppressed, and the long-term durability is further improved.

(Production of Back Sheet)

The back sheet for a solar cell of the invention may be produced by any method so long as the method is capable of forming the colored layer and the easy adhesion layer sequentially on a polymer substrate as described above. In the invention, the back sheet for a solar cell can be suitably produced by a production method comprising a step of applying, on a polymer substrate, a coating liquid for a colored layer and a coating liquid for an easy adhesion layer sequentially from the polymer substrate side (coating step) (method for producing a back sheet for a solar cell of the invention).

The (a) coating liquid for a colored layer is a coating liquid containing a pigment and a binder, and is used for forming a colored layer which contains a pigment in an amount of 2.5 g/m² to 8.5 g/m² and a binder. The (b) coating liquid for an easy adhesion layer is a coating liquid containing a binder and inorganic fine particles, and is used for forming an easy adhesion layer which contains a binder in an amount of 0.05 g/m² to 5 g/m² and inorganic fine particles in an amount of 5% by mass to 400% by mass based on the content of the binder, and has an adhesive power of 10 N/cm or greater with respect to an ethylene-vinyl acetate sealing material. The details of the components constituting the polymer substrate and the respective coating liquids, and the amount ranges of the components are as described above.

Suitable coating methods are also as described above, and for example, a gravure coater or a bar coater can be used.

The coating liquid for the colored layer is preferably an aqueous coating liquid in which 60% by mass or more of the solvent contained in this coating liquid is water. An aqueous coating liquid is preferable from the viewpoint of environmental load, and when the proportion of water is 60% by mass or greater, it is advantageous in that the environmental load is particularly decreased.

The proportion of water in the solvent in the coating liquid for the colored layer is preferably larger from the viewpoint of environmental load, and it is more preferable that water is contained in an amount of 90% by mass or greater of the total solvent amount.

In the coating step according to the invention, a colored layer can be formed on a polymer substrate by applying a coating liquid for the colored layer directly, or via an undercoat layer having a thickness of 2 μm or less, on the surface of the polymer substrate.

(Solar Cell Module)

The solar cell module of the invention is constructed by disposing a solar cell device which converts the light energy of sunlight into electrical energy, between a transparent substrate through which sunlight enters and the back sheet for a solar cell of the invention described above, and sealing the gap between the substrate and the back sheet with an ethylene-vinyl acetate sealing material.

The solar cell module, solar cell and members other than the back sheet are described in detail in, for example, “Constituent Materials for Solar Photovoltaic System” (edited by Sugimoto Eiichi, Kogyo Chosakai Publishing, Inc., published in 2008).

The transparent substrate has light transmissivity capable of transmitting sunlight, and the substrate can be appropriately selected from materials that are capable of transmitting light. From the viewpoint of power generation efficiency, a substrate having higher light transmittance is more preferable, and as such a substrate, for example, a glass substrate, or a transparent resin such as an acrylic resin can be preferably used.

As the solar cell device, various known solar cell devices such as silicon-based devices such as single crystal silicon, polycrystalline silicon and amorphous silicon; and Group III-V or Group II-VI compound semiconductors such as copper-indium-gallium-selenium, copper-indium-selenium, cadmium-tellurium and gallium-arsenic, can be applied.

### EXAMPLES

Hereinafter, the invention will be more specifically described with reference to Examples, but the invention is not intended to be limited to the following Examples. Unless particularly stated otherwise, the unit “part” is on a mass basis.

The volume average particle diameter was measured using a laser analysis/scattering type particle diameter distribution measuring apparatus LA950 (trade name, manufactured by Horiba, Ltd.).

### Example 1

### Production of Support

—Synthesis of Polyester—

A slurry of 100 kg of high purity terephthalic acid (manufactured by Mitsui Chemicals, Inc.) and 45 kg of ethylene glycol (manufactured by Nippon Shokubai Co., Ltd.) was sequentially supplied over 4 hours into an esterification reaction tank which had been previously charged with about 123 kg of bis(hydroxyethyl)terephthalate and was maintained at a temperature of 250° C. and at a pressure of 1.2×10⁵ Pa. Even after the completion of supply, the esterification reaction was performed for another one hour. Thereafter, 123 kg of the esterification reaction product thus obtained was transferred to a polycondensation reaction tank.

Subsequently, ethylene glycol was added to the polycondensation reaction tank to which the esterification reaction product was transferred, in an amount of 0.3% by mass based on the mass of the polymer to be obtained. After stirring for 5 minutes, an ethylene glycol solution of cobalt acetate and an ethylene glycol solution of manganese acetate were added in an amount of cobalt of 30 ppm and in an amount of manganese of 15 ppm, respectively, in the polymer to be obtained. After stirring the mixture for a further 5 minutes, a 2 mass % ethylene glycol solution of a titanium alkoxide compound was added to the mixture in an amount of titanium of 5 ppm in the polymer to be obtained. After 5 minutes, a 10 mass % ethylene glycol solution of ethyl diethylphosphonoacetate was added to the mixture in an amount of phosphorus of 5 ppm in the polymer to be obtained. Subsequently, while the oligomer was stirred at 30 rpm, the reaction system was slowly heated from 250° C. to 285° C., and the pressure was decreased to 40 Pa. The time to reach the final temperature and the final pressure was 60 minutes. At the time point at which a predetermined stirring torque was reached, the reaction system was purged with nitrogen and was returned to normal pressure, and the polycondensation reaction was terminated. Then, the reaction product was discharged into cold water in a strand shape, and the strand was immediately cut to produce pellets of the polymer (diameter about 3 mm, length about 7 mm). In addition, it took 3 hours to reach the predetermined stirring torque after the initiation of pressure reduction.

As the titanium alkoxide compound, the titanium alkoxide compound synthesized in Example 1 in paragraph [0083] of JP-A No. 2005-340616 (Ti content=4.44% by mass) was used.

—Solid State Polymerization—

The pellets obtained as described above were maintained at a temperature of 220° C. for 30 hours in a vacuum container maintained at 40 Pa, and thereby solid state polymerization was carried out.

—Formation of Base—

The pellets after the solid state polymerization as described above were melted at 280° C. and cast on a metal drum, and thereby an unstretched base having a thickness of about 3 mm was produced. Subsequently, the unstretched base was stretched to 3 times in the length direction at 90° C. and was stretched to 3.3 times in the width direction at 120° C. Thereby, a biaxially stretched polyethylene terephthalate support (hereinafter, referred to as “biaxially stretched PET”) having a thickness of 300 μm was obtained.

### Reflective Layer

—Preparation of Pigment Dispersion—

The components of the following composition were mixed, and the mixture was subjected to a dispersion treatment for one hour using a Dyno Mill type dispersing machine.

### Composition of Pigment Dispersion

| | |
|---|---|
| Titanium dioxide (volume average particle | 39.9% by mass |
| diameter = 0.42 μm) (TIPAQUE | |
| R-780-2, trade name, manufactured by Ishihara | |
| Sangyo Kaisha, Ltd., solid content 100% by mass) | |
| Polyvinyl alcohol (PVA-105, trade name, manufactured | 8.0% by mass |
| by Kuraray Co., Ltd., solid content: 10% by mass) | |
| Surfactant (DEMOL EP, trade name, manufactured | 0.5% by mass |
| by Kao Corp., solid content: 25% by mass) | |
| Distilled water | 51.6% by mass |

—Preparation of Coating Liquid for Reflective Layer—

The components of the following composition were mixed, and thus a coating liquid for reflective layer was prepared.

### Composition of Coating Liquid

| | |
|---|---|
| Pigment dispersion described above | 80.0% by mass |
| Aqueous dispersion liquid of polyacrylic | 19.2% by mass |
| resin (Binder: JURYMER ET410, trade name, | |
| manufactured by Nihon Junyaku co., | |
| Ltd., solid content: 30% by mass) | |
| Polyoxyalkylene alkyl ether (NAROACTY | 3.0% by mass |
| CL95, trade name, manufactured by | |
| Sanyo Chemical Industries, Ltd., | |
| solid content: 1% by mass) | |
| Oxazoline compound (EPOCROS WS-700, | 2.0% by mass |
| trade name, manufactured by Nippon | |
| Shokubai Co., Ltd., solid content: | |
| 25% by mass; crosslinking agent) | |
| Distilled water | 7.8% by mass |

—Formation of Reflective Layer—

The coating liquid thus obtained was applied on the biaxially stretched PET and was dried at 180° C. for one minute. Thus, a white layer (reflective layer) having an amount of titanium dioxide of 6.5 g/m² was formed as a pigment layer.

### Easy Adhesion Layer

—Preparation of Coating Liquid for Easy Adhesion Layer—

The components of the following composition were mixed, and a coating liquid for the easy adhesion layer was prepared.

### Composition of Coating Liquid

| | |
|---|---|
| Aqueous dispersion liquid of polyolefin resin (Binder: | 5.2% by mass |
| CHEMIPEARL S75N, trade name, manufactured by | |
| Mitsui Chemicals, Inc., solid content: 24% by mass) | |
| Polyoxyalkylene alkyl ether (NAROACTY CL95, | 7.8% by mass |
| trade name, manufactured by Sanyo Chemical | |
| Industries, Ltd., solid content: 1% by mass) | |
| Oxazoline compound (EPOCROS WS-700, trade | 0.8% by mass |
| name, manufactured by Nippon Shokubai Co., Ltd., | |
| solid content: 25% by mass: crosslinking agent) | |
| Aqueous dispersion of silica fine particles (AEROSIL | 2.9% by mass |
| OX-50, trade name, manufactured by Nippon Aerosil | |
| Co., Ltd., volume average particle diameter = | |
| 0.15 μm, solid content: 10% by mass) | |
| Distilled water | 83.3% by mass |

—Formation of Easy Adhesion Layer—

The coating liquid obtained was applied on the reflective layer so as to achieve an amount of binder of 0.09 g/m², and was dried for one minute at 180° C. Thus, an easy adhesion layer was formed.

As described above, the back sheet for a solar cell (hereinafter, referred to as “sample sheet”) of the invention was produced. This back sheet was subjected to evaluations of adhesiveness, adhesiveness after a lapse of time under moisture and heat, film strength and surface state according to the methods shown below. The results are shown in the following Table 1.

### Evaluation

—1. Adhesiveness—

[A] Adhesiveness Before Lapse of Time Under Moisture and Heat

A sample sheet produced as described above was cut to have a size of 20 mm in width×150 mm in length, and thus two sheets of sample strips were prepared. These two sheets of sample strips were arranged such that the easy adhesion layer side of each strip would face each other, and an EVA sheet (EVA sheet manufactured by Mitsui Chemicals Fabro, Inc.: SC50B, trade name) which had been previously cut to have a size of 20 mm in width×100 mm in length was interposed between the two sheets. The two sheets of sample strips were adhered to the EVA by hot pressing the assembly using a vacuum laminator (vacuum laminating machine manufactured by Nisshinbo Holdings, Inc.). The conditions for adhesion at this time were as shown below.

The assembly was subjected to a vacuum at 128° C. for 3 minutes using a vacuum laminator, and then provisional adhesion was achieved by pressing for 2 minutes. Thereafter, the assembly was subjected to a main adhesion treatment in a dry oven at 150° C. for 30 minutes. As such, there was obtained a sample for adhesion evaluation having an area which had a length of 20 mm from one edge of the two sheets of sample strips adhered to each other and remained unadhered to EVA, and having a remaining area which had a length of 100 mm and was adhered to the EVA sheet.

The EVA-unadhered area of the obtained sample for adhesion evaluation was clamped between upper and lower clips in a TENSILON (RTC-1210A, trade name, manufactured by Orientec Co., Ltd.), and a test was performed by drawing at a peeling angle of 180° and a rate of pulling of 300 mm/min. Thus the adhesive power was measured.

The adhesive power thus measured was used to grade the samples according to the following evaluation criteria. Among these, grades 4 and 5 fall in the practically acceptable range.

### Evaluation Criteria

5: The adhesion was very good (60 N/20 mm or greater)

4: The adhesion was good (from 30 N/20 mm to less than 60 N/20 mm)

3: The adhesion was slightly poor (from 20 N/20 mm to less than 30 N/20 mm)

2: Adhesion failure occurred (from 10 N/20 mm to less than 20 N/20 mm)

1: Adhesion failure was noticeable (less than 10 N/20 mm)

[B] Adhesiveness after Time Lapse Under Moisture and Heat

A sample for adhesion evaluation thus obtained was stored for 48 hours under the environmental conditions of 120° C. and 100% RH (a time lapse under moisture and heat), and then the adhesive power was measured by the same method as in the section [A] above. The ratio of the measured adhesive power after storage to the [A] adhesive power of the same sample for adhesion evaluation prior to the time lapse under moisture and heat [%=adhesive power after a time lapse under moisture and heat/[A] adhesive power prior to a time lapse under moisture and heat×100] was calculated. Furthermore, the adhesive power was evaluated by the same method as in the section [A], based on the measured adhesive power after a lapse of time under moisture and heat.

—2. Film Strength—

A sample sheet produced as described above was stored for 2 hours in an atmosphere at 25° C. and 65% RH, and then a rubbing test was performed by rubbing the sample sheet together with a black paper under a load of 1 kg/cm in width at a rate of 2460 mm/minute. The degree of powder fall-off of the coating layer on the black paper after the rubbing test was visually observed, and the degree of powder fall-off was evaluated according to the following evaluation criteria. Among these, grades 3, 4 and 5 fall in the practically acceptable range.

### Evaluation Criteria

5: There was no powder fall-off.

4: Powder fall-off was observed very slightly.

3: Slight powder fall-off was observed.

2: Strong powder fall-off was observed.

1: Powder fall-off was observed over almost the entire surface of the black paper.

—3. Surface State—

The surface state of a sample sheet produced as described above was visually observed and evaluated according to the following evaluation criteria. Among these, grades 3, 4 and 5 fall in the practically acceptable range.

### Evaluation Criteria

5: Unevenness or cissing was not at all observed.

4: Unevenness was very slightly observed, but cissing was not confirmed.

3: Unevenness was slightly observed, but cissing was not confirmed.

2: Unevenness was clearly confirmed, and cissings were observed in some areas (fewer than 10 cissings/m²).

1: Unevenness was clearly confirmed, and 10 or more cissings/m² were observed.

—4. Reflectance—

The reflectance of light of 550 nm at the side of the surface of the sample sheet where the reflective layer and easy adhesion layer were formed, was measured using a spectrophotometer UV-2450 (trade name, manufactured by Shimadzu Corp.) equipped with an integrating sphere accessory equipment ISR-2200 (trade name). Here, the reflectance of a barium sulfate standard plate was measured as a reference, and the reflectance of the sample sheet was calculated by taking the reference reflectance as 100%.

—5. Carboxy Group Content of Biaxially Stretched PET—

The weight w [g] of about 0.1 g of a biaxially stretched PET was measured, this was placed in a round-bottom flask containing 5 mL of benzyl alcohol, and the flask was maintained at a temperature of 205° C. for 24 hours while capped. Thereafter, the content was added to 15 mL of chloroform. A small amount of a phenol red indicator was added to this liquid, and the liquid was titrated with a benzyl alcohol solution of potassium hydroxide with a concentration of 0.01 N/L. The amount of carboxy groups (amount of COOH groups) of the biaxially stretched PET was determined by the following formula, while designating the amount of the potassium hydroxide solution required in the titration as x mL.

Carboxy group content(equivalent/t)=0.01×x/w

### Examples 2 to 18 and Comparative Examples 1 to 10

Back sheets for a solar cell (sample sheets) were produced in the same manner as in Example 1, except that the amount of pigment coating and the amount of binder coating in the reflective layer, and the amount of binder coating and the amount of inorganic fine particle coating in the easy adhesion layer as used in Example 1 were changed as indicated in the following Table 1, and at the same time, the sample sheets were subjected to evaluation. The evaluation results are shown in the following Table 1.

However, in Comparative Examples 9 and 10, the easy adhesion layer was not provided, and the reflective layer in the Comparative Example 10 was subjected to a corona treatment at an output power of 1.3 kW/1 m of electrode (represents the output power per 1 m of the electrode) and a treatment intensity of 500 J/m².

### Examples 19 and 20 and Comparative Examples 11 to 14

Back sheets for a solar cell (sample sheets) were produced in the same manner as in Example 1, except that titanium dioxide used in Example 1 was replaced with ultramarine blue [ULTRAMARINE BLUE NUBIFLOW, trade name, manufactured by Ozeki Co., Ltd.] or carbon black (TOKABLACK #8500F, trade name, manufactured by Tokai Carbon Co., Ltd.), and the presence or absence of the easy adhesion layer was changed as indicated in the following Table 1, and at the same time, the sample sheets were subjected to evaluation. The evaluation results are shown in the following Table 1.

However, the presence or absence of the easy adhesion layer and the corona treatment are as shown in the following Table 1. The measurement of the reflectance was not carried out.

### Examples 21 and 22

Back sheets for a solar cell (sample sheets) were produced in the same manner as in Example 1, except that the melting temperature used in Example 1 to produce the biaxially stretched PET in the section “Formation of base” was raised from 280° C. to 295° C. (Example 21) and 310° C. (Example 22), and at the same time, the sample sheets were subjected to evaluation. The evaluation results are shown in the following Table 1.

### Examples 23 to 25

Back sheets for a solar cell (sample sheets) were produced in the same manner as in Examples 1, 21 and 22, except that an undercoat layer as shown below was provided on the biaxially stretched PET used in Examples 1, 21 and 22, and at the same time, the sample sheets were subjected to evaluation. The evaluation results are shown in the following Table 1.

—Formation of Undercoat Layer—

An undercoat layer liquid was prepared by mixing the components of the following composition, and this undercoat layer liquid was applied on the biaxially stretched PET. Subsequently, the liquid was dried at 180° C. for one minute, and thus an undercoat layer having an amount of coating of about 0.1 g/m² (thickness: about 0.1 μm) was formed.

### Composition of Undercoat Layer

| | |
|---|---|
| Polyester resin | 1.7% by mass |
| (VYLONAL MD-1200, trade name, manufactured by | |
| Toyobo Co., Ltd., solid content: 17% by mass) | |
| Polyester resin (PESRESIN | 3.8% by mass |
| A-520, trade name, manufactured by Takamatsu | |
| Oil & Fat Co., Ltd., solid content: 30% by mass) | |
| Polyoxyalkylene alkyl ether (NAROACTY | 1.5% by mass |
| CL95, trade name, manufactured by Sanyo Chemical | |
| Industries, Ltd., solid content: 1% by mass) | |
| Carbodiimide compound (CARBODILITE | 1.3% by mass |
| V-02-L2, trade name, manufactured by Nisshinbo | |
| Holdings, Inc., solid content: 10% by mass) | |
| Distilled water | 91.7% by mass |

### Examples 26 to 39

Back sheets for a solar cell (sample sheets) were produced in the same manner as in Example 1, except that the compositions of the reflective layer and the easy adhesion layer used in Example 1 were changed as indicated in the following Table 1, and at the same time, the sample sheets were subjected to evaluation. The evaluation results are shown in the following Table 1.

### Example 40

A reinforced glass having a thickness of 3 mm, an EVA sheet (SC50B, trade name, manufactured by Mitsui Chemicals Fabro, Inc.), a crystal-based solar cell, an EVA sheet (SC50B, trade name, manufactured by Mitsui Chemicals Fabro, Inc.), and the sample sheet of Example 1 (back sheet for a solar cell of the invention) were stacked in this order, and then hot pressed using a vacuum laminator (manufactured by Nisshinbo Holdings, Inc., vacuum laminating machine) to adhere with EVA. At this time, the sample sheet was disposed such that the easy adhesion layer was in contact with the EVA sheet. Furthermore, the adhesion conditions for the EVA were as follows.

The assembly was subjected to a vacuum at 128° C. for 3 minutes using a vacuum laminator, and then provisional adhesion was achieved by pressing for 2 minutes. Thereafter, the assembly was subjected to a main adhesion treatment in a dry oven at 150° C. for 30 minutes.

As such, a crystal-based solar cell module was produced. The solar cell module thus produced was used to perform power generation, and the solar cell module exhibited satisfactory power generation performance as a solar cell.

TABLE 1

| | | | Reflective layer | | | Easy adhesion layer | | |
|---|---|---|---|---|---|---|---|---|
| | Polymer | Presence | | | Crosslinking | | Amount of | Crosslinking |
| | substrate | or absence | Type of pigment/ | Amount | agent (%, | Amount | inorganic | agent (%, |
| | COOH group | of undercoat | Amount added | of binder | based on | of binder | fine particles | based on |
| | content | layer | [g/m²] | [g/m²] | binder) | [g/m²] | [g/m²] | binder) |
| Example 1 | 29 | Absent | TiO2/6.5 | 1.2 | 30 | 0.09 | 0.02 | 30 |
| Comparative | 29 | Absent | TiO2/1.5 | 1.2 | 30 | 0.09 | 0.02 | 30 |
| Example 1 | | | | | | | | |
| Example 2 | 29 | Absent | TiO2/3.5 | 1.2 | 30 | 0.09 | 0.02 | 30 |
| Example 3 | 29 | Absent | TiO2/4.5 | 1.2 | 30 | 0.09 | 0.02 | 30 |
| Example 4 | 29 | Absent | TiO2/8.0 | 1.2 | 30 | 0.09 | 0.02 | 30 |
| Comparative | 29 | Absent | TiO2/9.0 | 1.2 | 30 | 0.09 | 0.02 | 30 |
| Example 2 | | | | | | | | |
| Example 5 | 29 | Absent | TiO2/6.5 | 0.8 | 30 | 0.09 | 0.02 | 30 |
| Example 6 | 29 | Absent | TiO2/6.5 | 1.0 | 30 | 0.09 | 0.02 | 30 |
| Example 7 | 29 | Absent | TiO2/6.5 | 3.2 | 30 | 0.09 | 0.02 | 30 |
| Example 8 | 29 | Absent | TiO2/6.5 | 6.2 | 30 | 0.09 | 0.02 | 30 |
| Example 9 | 29 | Absent | TiO2/6.5 | 9.8 | 30 | 0.09 | 0.02 | 30 |
| Example 10 | 29 | Absent | TiO2/6.5 | 12 | 30 | 0.09 | 0.02 | 30 |
| Example 11 | 29 | Absent | TiO2/6.5 | 15 | 30 | 0.09 | 0.02 | 30 |
| Comparative | 29 | Absent | TiO2/6.5 | 1.2 | 30 | 0.03 | 0.02 | 30 |
| Example 3 | | | | | | | | |
| Example 12 | 29 | Absent | TiO2/6.5 | 1.2 | 30 | 0.06 | 0.02 | 30 |
| Example 13 | 29 | Absent | TiO2/6.5 | 1.2 | 30 | 1.5 | 0.02 | 30 |
| Comparative | 29 | Absent | TiO2/6.5 | 1.2 | 30 | 3 | 0.02 | 30 |
| Example 4 | | | | | | | | |
| Comparative | 29 | Absent | TiO2/6.5 | 1.2 | 30 | 4.5 | 0.02 | 30 |
| Example 5 | | | | | | | | |
| Comparative | 29 | Absent | TiO2/6.5 | 1.2 | 30 | 6 | 0.02 | 30 |
| Example 6 | | | | | | | | |
| Comparative | 29 | Absent | TiO2/6.5 | 1.2 | 30 | 0.09 | 0 | 30 |
| Example 7 | | | | | | | | |
| Example 14 | 29 | Absent | TiO2/6.5 | 1.2 | 30 | 0.09 | 0.01 | 30 |
| Example 15 | 29 | Absent | TiO2/6.5 | 1.2 | 30 | 0.09 | 0.05 | 30 |
| Example 16 | 29 | Absent | TiO2/6.5 | 1.2 | 30 | 0.09 | 0.15 | 30 |
| Example 17 | 29 | Absent | TiO2/6.5 | 1.2 | 30 | 0.09 | 0.25 | 30 |
| Example 18 | 29 | Absent | TiO2/6.5 | 1.2 | 30 | 0.09 | 0.35 | 30 |
| Comparative | 29 | Absent | TiO2/6.5 | 1.2 | 30 | 0.09 | 0.45 | 30 |
| Example 8 | | | | | | | | |
| Comparative | 29 | Absent | TiO2/6.5 | 1.2 | 30 | (*1) | | |
| Example 9 | | | | | | | | |
| Comparative | 29 | Absent | TiO2/6.5 | 1.2 | 30 | (*1) | | |
| Example 10 | | | | | | | | |
| Example 19 | 29 | Absent | Ultramarine | 1.2 | 30 | 0.09 | 0.02 | 30 |
| | | | blue/6.5 | | | | | |
| Comparative | 29 | Absent | Ultramarine | 1.2 | 30 | (*1) | | |
| Example 11 | | | blue/6.5 | | | | | |
| Comparative | 29 | Absent | Ultramarine | 1.2 | 30 | (*1) | | |
| Example 12 | | | blue/6.5 | | | | | |
| Example 20 | 29 | Absent | CB/6.5 | 1.2 | 30 | 0.09 | 0.02 | 30 |
| Comparative | 29 | Absent | CB/6.5 | 1.2 | 30 | (*1) | | |
| Example 13 | | | | | | | | |
| Comparative | 29 | Absent | CB/6.5 | 1.2 | 30 | (*1) | | |
| Example 14 | | | | | | | | |
| Example 21 | 41 | Absent | TiO2/6.5 | 1.2 | 30 | 0.09 | 0.02 | 30 |
| Example 22 | 53 | Absent | TiO2/6.5 | 1.2 | 30 | 0.09 | 0.02 | 30 |
| Example 23 | 29 | Present | TiO2/6.5 | 1.2 | 30 | 0.09 | 0.02 | 30 |
| Example 24 | 29 | Present | Ultramarine | 1.2 | 30 | 0.09 | 0.02 | 30 |
| | | | blue/6.5 | | | | | |
| Example 25 | 29 | Present | CB/6.5 | 1.2 | 30 | 0.09 | 0.02 | 30 |
| Example 26 | 29 | Absent | TiO2/6.5 | 1.2 | 0 | 0.09 | 0.02 | 30 |
| Example 27 | 29 | Absent | TiO2/6.5 | 1.2 | 10 | 0.09 | 0.02 | 30 |
| Example 28 | 29 | Absent | TiO2/6.5 | 1.2 | 20 | 0.09 | 0.02 | 30 |
| Example 29 | 29 | Absent | TiO2/6.5 | 1.2 | 40 | 0.09 | 0.02 | 30 |
| Example 30 | 29 | Absent | TiO2/6.5 | 1.2 | 50 | 0.09 | 0.02 | 30 |
| Example 31 | 29 | Absent | TiO2/6.5 | 1.2 | 60 | 0.09 | 0.02 | 30 |
| Example 32 | 29 | Absent | TiO2/6.5 | 1.2 | 30 | 0.09 | 0.02 | 0 |
| Example 33 | 29 | Absent | TiO2/6.5 | 1.2 | 30 | 0.09 | 0.02 | 10 |
| Example 34 | 29 | Absent | TiO2/6.5 | 1.2 | 30 | 0.09 | 0.02 | 20 |
| Example 35 | 29 | Absent | TiO2/6.5 | 1.2 | 30 | 0.09 | 0.02 | 40 |
| Example 36 | 29 | Absent | TiO2/6.5 | 1.2 | 30 | 0.09 | 0.02 | 50 |
| Example 37 | 29 | Absent | TiO2/6.5 | 1.2 | 30 | 0.09 | 0.02 | 60 |
| Example 38 | 29 | Absent | Ultramarine | 1.2 | 0 | 0.09 | 0.02 | 0 |
| | | | blue/6.5 | | | | | |
| Example 39 | 29 | Absent | CB/6.5 | 1.2 | 0 | 0.09 | 0.02 | 0 |

| | | Adhesiveness | | | | | |
|---|---|---|---|---|---|---|---|
| | Presence | Grade prior to | Grade after | | | | |
| | or absence | time lapse | time lapse | | | | |
| | of corona | under moisture | under moisture | | Film | Surface | Reflectance |
| | treatment | and heat | and heat [%] | | strength | state | [%] |
| Example 1 | Absent | 5 | 5 | 80 | 5 | 5 | 82 |
| Comparative | Absent | 5 | 5 | 70 | 5 | 5 | 62 |
| Example 1 | | | | | | | |
| Example 2 | Absent | 5 | 5 | 75 | 5 | 5 | 76 |
| Example 3 | Absent | 5 | 5 | 80 | 5 | 5 | 81 |
| Example 4 | Absent | 5 | 5 | 80 | 5 | 5 | 82 |
| Comparative | Absent | 5 | 5 | 70 | 1 | 2 | 81 |
| Example 2 | | | | | | | |
| Example 5 | Absent | 5 | 5 | 75 | 3 | 3 | 82 |
| Example 6 | Absent | 5 | 5 | 85 | 5 | 5 | 83 |
| Example 7 | Absent | 5 | 5 | 90 | 5 | 5 | 83 |
| Example 8 | Absent | 5 | 5 | 85 | 5 | 5 | 82 |
| Example 9 | Absent | 5 | 5 | 85 | 5 | 5 | 82 |
| Example 10 | Absent | 5 | 5 | 80 | 5 | 5 | 82 |
| Example 11 | Absent | 5 | 5 | 75 | 5 | 5 | 82 |
| Comparative | Absent | 3 | 3 | 45 | 2 | 5 | 82 |
| Example 3 | | | | | | | |
| Example 12 | Absent | 5 | 5 | 75 | 5 | 5 | 81 |
| Example 13 | Absent | 5 | 5 | 80 | 5 | 5 | 82 |
| Comparative | Absent | 5 | 5 | 90 | 2 | 4 | 80 |
| Example 4 | | | | | | | |
| Comparative | Absent | 5 | 5 | 85 | 1 | 2 | 82 |
| Example 5 | | | | | | | |
| Comparative | Absent | 5 | 4 | 70 | 5 | 1 | 80 |
| Example 6 | | | | | | | |
| Comparative | Absent | 5 | 2 | 50 | 5 | 5 | 82 |
| Example 7 | | | | | | | |
| Example 14 | Absent | 5 | 5 | 75 | 5 | 5 | 82 |
| Example 15 | Absent | 5 | 5 | 85 | 5 | 5 | 81 |
| Example 16 | Absent | 5 | 5 | 75 | 5 | 5 | 81 |
| Example 17 | Absent | 5 | 5 | 90 | 5 | 5 | 81 |
| Example 18 | Absent | 5 | 5 | 80 | 5 | 5 | 80 |
| Comparative | Absent | 5 | 5 | 65 | 2 | 2 | 81 |
| Example 8 | | | | | | | |
| Comparative | Absent | 4 | 1 | 10 | 5 | 5 | 82 |
| Example 9 | | | | | | | |
| Comparative | Present | 5 | 2 | 10 | 5 | 5 | 82 |
| Example 10 | | | | | | | |
| Example 19 | Absent | 5 | 5 | 85 | 5 | 5 | — |
| Comparative | Absent | 4 | 1 | 10 | 5 | 5 | — |
| Example 11 | | | | | | | |
| Comparative | Present | 5 | 1 | 10 | 5 | 5 | — |
| Example 12 | | | | | | | |
| Example 20 | Absent | 5 | 5 | 85 | 5 | 5 | — |
| Comparative | Absent | 4 | 1 | 10 | 5 | 5 | — |
| Example 13 | | | | | | | |
| Comparative | Present | 5 | 2 | 10 | 5 | 5 | — |
| Example 14 | | | | | | | |
| Example 21 | Absent | 5 | 4 | 75 | 5 | 5 | 82 |
| Example 22 | Absent | 5 | 4 | 75 | 5 | 5 | 79 |
| Example 23 | Absent | 5 | 5 | 95 | 5 | 5 | 81 |
| Example 24 | Absent | 5 | 5 | 90 | 5 | 5 | — |
| Example 25 | Absent | 5 | 5 | 90 | 5 | 5 | — |
| Example 26 | Absent | 5 | 4 | 75 | 5 | 5 | 82 |
| Example 27 | Absent | 5 | 5 | 80 | 5 | 5 | 82 |
| Example 28 | Absent | 5 | 5 | 85 | 5 | 5 | 81 |
| Example 29 | Absent | 5 | 5 | 80 | 5 | 5 | 82 |
| Example 30 | Absent | 5 | 5 | 90 | 5 | 5 | 82 |
| Example 31 | Absent | 5 | 5 | 80 | 5 | 3 | 79 |
| Example 32 | Absent | 5 | 4 | 75 | 5 | 5 | 82 |
| Example 33 | Absent | 5 | 5 | 85 | 5 | 5 | 82 |
| Example 34 | Absent | 5 | 5 | 80 | 5 | 5 | 82 |
| Example 35 | Absent | 5 | 5 | 90 | 5 | 5 | 81 |
| Example 36 | Absent | 5 | 5 | 85 | 5 | 5 | 81 |
| Example 37 | Absent | 5 | 5 | 85 | 5 | 3 | 82 |
| Example 38 | Absent | 5 | 4 | 75 | 5 | 5 | — |
| Example 39 | Absent | 5 | 4 | 80 | 5 | 5 | — |

(*1) The easy adhesion layer is absent.

As shown in Table 1, the Examples were excellent in terms of the adhesiveness with respect to an EVA sealing material and reflectivity, and the solar cell modules thus obtained exhibited satisfactory power generation performance. On the contrary, the Comparative Examples exhibited decrease in reflectance, or even though the reflectance was maintained, the adhesiveness (particularly, adhesiveness after a lapse of time under moisture and heat) was significantly decreased.

Japanese Patent Application No. 2010-008596 is incorporated herein by reference.

All publications, patent applications, and technical standards mentioned in this specification are herein incorporated by reference to the same extent as if each individual publication, patent application, or technical standard was specifically and individually indicated to be incorporated by reference.

1-12. (canceled)

13. A back sheet for a solar cell, comprising on a polymer substrate:
a colored layer which contains a first binder and 2.5 g/m² to 8.5 g/m² of a pigment; and
an easy adhesion layer which contains 0.05 g/m² to 5 g/m² of a second binder and 5% by mass to 400% by mass of inorganic fine particles based on the content of the second binder and has an adhesive power of 10 N/cm or greater with respect to an ethylene-vinyl acetate sealing material,
in this order from the side of the polymer substrate.

14. The back sheet for a solar cell according to claim 13, wherein the colored layer further contains 5% by mass to 50% by mass of a crosslinking agent based on the content of the first binder.

15. The back sheet for a solar cell according to claim 13, wherein the easy adhesion layer further contains 5% by mass to 50% by mass of a crosslinking agent based on the content of the second binder.

16. The back sheet for a solar cell according to claim 15, wherein the adhesive power with respect to the sealing material after storage of the back sheet for 48 hours in an atmosphere at 120° C. and 100% RH is at least 75% of the adhesive power with respect to the sealing material prior to the storage.

17. The back sheet for a solar cell according to claim 14, wherein the colored layer is disposed directly, or via an undercoat layer having a thickness of 2 μm or less, on a surface of the polymer substrate.

18. The back sheet for a solar cell according to claim 14, wherein the pigment is a white pigment, and a reflectance of light having a wavelength of 550 nm on a surface of the back sheet where the colored layer and the easy adhesion layer are provided is 75% or greater.

19. The back sheet for a solar cell according to claim 14, wherein the polymer substrate comprises a polyester having a carboxy group content of 35 equivalents/ton or less.

20. The back sheet for a solar cell according to claim 16, wherein the colored layer and the easy adhesion layer are formed by coating.

21. A solar cell module comprising a transparent substrate through which sunlight enters, a solar cell device, and a back sheet for a solar cell,
the back sheet for a solar cell, comprising on a polymer substrate:
a colored layer which contains a first binder and 2.5 g/m² to 8.5 g/m² of a pigment; and
an easy adhesion layer which contains 0.05 g/m² to 5 g/m² of a second binder and 5% by mass to 400% by mass of inorganic fine particles based on the content of the second binder and has an adhesive power of 10 N/cm or greater with respect to an ethylene-vinyl acetate sealing material,
in this order from the side of the polymer substrate.

22. A method for producing a back sheet for a solar cell, the method comprising applying, on a polymer substrate, a first coating liquid which contains a first binder and a pigment, and a second coating liquid which contains a second binder and inorganic fine particles, in this order from the polymer substrate side, thereby forming a colored layer which contains the first binder and 2.5 g/m² to 8.5 g/m² of the pigment, and an easy adhesion layer which contains 0.05 g/m² to 5 g/m² of the second binder and 5% by mass to 400% by mass of the inorganic fine particles based on the content of the second binder and has an adhesive power of 10 N/cm or greater with respect to an ethylene-vinyl acetate sealing material.

23. The method for producing a back sheet for a solar cell according to claim 22, wherein the first coating liquid further contains a solvent and is an aqueous coating liquid in which 60% by mass or more of the solvent is water.

24. The method for producing a back sheet for a solar cell according to claim 22, wherein the colored layer is formed on the polymer substrate by applying the first coating liquid directly, or via an undercoat layer having a thickness of 2 μm or less, on a surface of the polymer substrate.

25. The solar cell module according to claim 21, wherein the colored layer further contains 5% by mass to 50% by mass of a crosslinking agent based on the content of the first binder.

26. The solar cell module according to claim 21, wherein the easy adhesion layer further contains 5% by mass to 50% by mass of a crosslinking agent based on the content of the second binder.

27. The solar cell module according to claim 26, wherein the adhesive power with respect to the sealing material after storage of the back sheet for 48 hours in an atmosphere at 120° C. and 100% RH is at least 75% of the adhesive power with respect to the sealing material prior to the storage.

28. The solar cell module according to claim 25, wherein the colored layer is disposed directly, or via an undercoat layer having a thickness of 2 μm or less, on a surface of the polymer substrate.

29. The solar cell module according to claim 25, wherein the pigment is a white pigment, and a reflectance of light having a wavelength of 550 nm on a surface of the back sheet where the colored layer and the easy adhesion layer are provided is 75% or greater.

30. The solar cell module according to claim 25, wherein the polymer substrate comprises a polyester having a carboxy group content of 35 equivalents/ton or less.

31. The solar cell module according to claim 27, wherein the colored layer and the easy adhesion layer are formed by coating.

32. The method for producing a back sheet for a solar cell according to claim 23, wherein the colored layer is formed on the polymer substrate by applying the first coating liquid directly, or via an undercoat layer having a thickness of 2 μm or less, on a surface of the polymer substrate.
